(19) United States
(12) Patent Application Publication
(10) Pub. No.: US 2005/0037136 A1
(43) Pub. Date: Feb. 17, 2005

(54) Mask for deposition, film formation method using the same and film formation equipment using the same

(76) Inventor: Katsuya Yamamoto, Kariya-shi (JP)

Correspondence Address: MORGAN & FINNEGAN, L.L.P., 3 WORLD FINANCIAL CENTER, NEW YORK, NY, 10281-2101, US

(21) Appl. No.: 10/899,375

(22) Filed: Jul. 26, 2004

(30) Foreign Application Priority Data
Jul. 28, 2003 (JP) P2003-202146

(51) Int. Cl. B05D 5/12

(52) U.S. Cl. 427/66

(57) ABSTRACT

A mask is interposed between a deposition source and a substrate for deposition. The mask has an opening for permitting a deposition material emitted from the deposition source to pass therethrough and forming a deposition layer of a desired pattern on the substrate. The mask includes a mask body and a heating member. The mask body has the opening. The heating member is heated during deposition and is arranged on a side of the mask body facing the deposition source. The heating member has an opening which corresponds substantially to the opening of the mask body.

### BACKGROUND OF THE INVENTION

The present invention relates to a mask for deposition, a film formation method using the mask and a film formation equipment using the mask.

An organic electroluminescent (EL) element including a pair of electrodes that consists of an anode and a cathode and are provided on a substrate, and an organic layer containing a light-emitting organic material and formed between the pair of electrodes has been known as an element capable of emitting light from the organic layer by passing current between the electrodes. The organic layer of the organic EL element typically includes a plurality of functional layers (a hole injection layer, a hole transport layer, a luminous layer, an electron transport layer, an electron injection layer, a buffer layer, a carrier blocking layer, etc.) and achieves a desired performance through combination, arrangement, etc. of those functional layers.

For an organic EL element of a low molecular material among organic EL elements having the above-stated configuration, it is typical that an organic material is deposited using a vacuum deposition process on a substrate to form an organic layer.

In the vacuum deposition process, an organic material for forming an organic layer is put in a deposition source with outlets, and the deposition source is heated in a chamber where vacuum is kept at a prescribed value to emit an evaporated organic material through the outlets, and the emitted organic material is deposited on a substrate apart from the deposition source.

Generally, different functional layers are formed in different chambers. The reason for this is that when materials making up other functional layers get mixed in with a functional layer of interest, the performance to be achieved by an organic EL element is degraded and such phenomenon has to be prevented.

In the manufacture of such organic EL element, organic layers having a desired pattern are in many cases formed on a substrate and a so-called shadow mask method using a mask has been known (refer to, for example, Japanese Unexamined Patent Publication No. 2001-247959, pages 2-3 and FIG. 1 thereof).

For instance, a mask 50 shown in FIGS. 10A and 10B is used in the shadow mask method and disposed between a deposition source 51 and a substrate 52 in a chamber not shown, and such mask 50 typically has a plurality of openings 50a provided to correspond to a pattern.

In this case, the deposition source 51 is located below the substrate 52, and reciprocates relatively to the mask 50 and the substrate 52 at the time of deposition and the organic material is continuously emitted from the deposition source 51 until formation of an organic layer on the substrate 52.

Accordingly, a portion of the organic material emitted from the deposition source 51 passes through the openings 50a and the organic material having passed therethrough is deposited on the substrate 52 to form an organic layer corresponding to a pattern on the substrate 52.

It is noted that the mask 50 for formation of the organic layers of the organic EL element generally has a thickness of about 0.2 mm and is made of metal.

However, the above-described conventional mask includes the following problems.

That is, a significant amount of the organic material as a deposition material emitted from the deposition source has been deposited on the mask.

When deposition is repeated, the thickness of the deposition material deposited on the mask cannot be ignored compared to the thickness of the mask, resulting in adverse effect on quality of deposited layers. Accordingly, the mask must be replaced frequently.

Further, for example when the organic layers of the organic EL element consist of a plurality of functional layers, the mask has to be replaced when each of the functional layers is formed.

Moreover, the mask receives heat from the deposition material and radiated heat from the deposition source, and undergoes thermal expansion, potentially decreasing the dimensional accuracy of the deposition layer on the substrate.

In particular, as a substrate becomes larger in size, changes in dimensions due to thermal expansion of the mask become more distinguished around peripheries of the substrate, and in some cases, the dimensional accuracy of the deposition layers is also decreased.

Such failure occurs when an area of the substrate, on which area the organic layers are to be deposited, is small as well as when a substrate is in large size.

In addition, the deposition material is deposited on an area other than a prescribed area (area corresponding to the openings of the mask) of the substrate and therefore the utilization efficiency of the deposition material is low.

### SUMMARY OF THE INVENTION

The present invention is directed to a mask for deposition, a film formation method using the mask and a film formation equipment using the mask, wherein deposition of a deposition material on the mask is suppressed during formation of a deposition layer on a substrate using the mask, the deposition layer on the substrate with a high dimensional accuracy is formed and the utilization efficiency of the deposition material is improved.

The present invention provides a mask interposed between a deposition source and a substrate for deposition. The mask has an opening for permitting a deposition material emitted from the deposition source to pass therethrough and forming a deposition layer of a desired pattern on the substrate. The mask includes a mask body and a heating member. The mask body has the opening. The heating member is heated during deposition and is arranged on a side of the mask body facing the deposition source. The heating member has an opening which corresponds substantially to the opening of the mask body.

The present invention provides a film formation method using a mask for forming a deposition layer of a desired pattern on a substrate. The mask includes a mask body and a heating member. The method includes the steps of: fixing the substrate and the mask so that the mask body faces the substrate; providing a deposition source that emits a deposition material so as to face a side of the mask corresponding to the heating member; and heating the heating member of the mask while depositing the deposition material on the substrate.

The present invention provides a film formation equipment for forming a deposition layer on a substrate. The film formation equipment includes a deposition source and a mask. The deposition source emits a deposition material toward the substrate. The mask is interposed between the substrate and the deposition source for forming a deposition layer of a desired pattern on the substrate. The mask includes a mask body and a heating member which is arranged on a side of the mask body facing the deposition source.

Other aspects and advantages of the invention will become apparent from the following description, taken in conjunction with the accompanying drawings, illustrating by way of example the principles of the invention.

### BRIEF DESCRIPTION OF THE DRAWINGS

The features of the present invention that are believed to be novel are set forth with particularity in the appended claims. The invention, together with objects and advantages thereof, may best be understood by reference to the following description of the presently preferred embodiments, together with the accompanying drawings, in which:

FIG. 1 is a schematic sectional view illustrating an organic electroluminescent element according to a first embodiment of the invention;

FIG. 2 is a schematic perspective view illustrating a film formation equipment according to the first embodiment of the invention;

FIG. 3 is a side view illustrating the film formation equipment which is partially cut away according to the first embodiment of the invention;

FIG. 4 is a side view illustrating structure of a mask for deposition which is partially cut away according to the first embodiment of the invention;

FIG. 5 is a partial side view illustrating a mask for deposition which has a contacting member and is partially cut away according to the first embodiment of the invention;

FIG. 6 is a side view illustrating structure of a mask for deposition which is partially cut away, according to a second embodiment of the invention;

FIG. 7 is a side view illustrating structure of a mask for deposition which is partially cut away, according to a first modification example of the second embodiment of the invention;

FIG. 8 is a side view illustrating structure of a mask for deposition which is partially cut away, according to a second modification example of the second embodiment of the invention;

FIG. 9 is a side view illustrating structure of a mask for deposition which is partially cut away, according to a third embodiment of the invention;

FIG. 10A is a plane view illustrating a prior art film formation equipment which is partially cut away; and

FIG. 10B is a sectional view illustrating the prior art film formation equipment as seen from the line A-A in FIG. 10A.

### DETAILED DESCRIPTION OF THE PREFERRED EMBODIMENTS

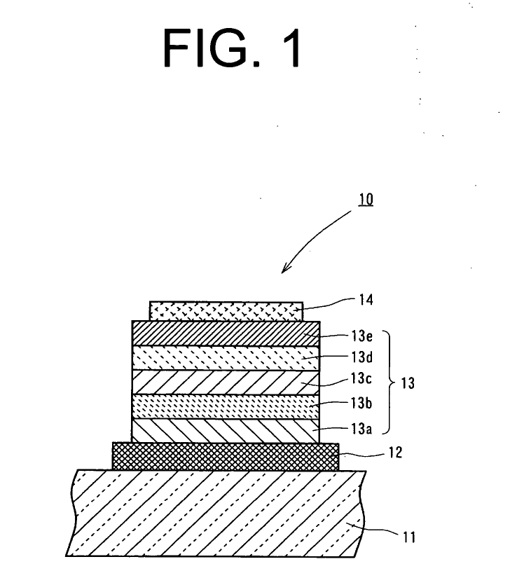

A first embodiment of the invention will be explained below with reference to FIGS. 1 to 4.

The first embodiment is implemented by applying the invention to deposition of organic layers in an organic EL element.

First, the organic EL element is explained. As shown in FIG. 1, an organic EL element 10 essentially includes a glass substrate 11, an anode 12, an organic layer 13, and a cathode 14.

The glass substrate 11 allows visible light to transmit therethrough and has the anode 12 as a transparent conductive layer formed on one surface of the glass substrate 11. The anode 12 is made of ITO (Indium Tin Oxide) or the like and is formed, for example, by sputtering.

Then, in the embodiment, as shown in FIG. 1, laminated on the anode 12 are a hole injection layer 13a, a hole transport layer 13b, a luminous layer 13c, an electron transport layer 13d, and an electron injection layer 13e in this order. In the embodiment, a combination of those functional layers is referred to as a whole as an organic layer 13.

All the layers 13a to 13e are made of organic materials whose types are different from one another and are formed as layers by depositing organic materials as a deposition material by a vacuum deposition process.

The term “substrate” used herein includes at least a plate member such as the glass substrate 11 on which the anode 12 has been formed and deposition materials such as organic materials will be evaporated.

For instance, the glass substrate 11 having only the anode 12 formed thereon, and the glass substrate 11 having the hole injection layer 13a, the hole transport layer 13b, the luminous layer 13c, the electron transport layer 13d, and the anode 12 formed thereon are included in the conceptual expression “substrate” used herein.

Further, the cathode 14 is formed on the organic layer 13 and is an electrode for injecting electrons into the electron injection layer 13e, and is deposited on the electron injection layer 13e typically by deposition technique.

Thus the constructed organic EL element 10 is operated so that direct current is applied to the anode 12 and cathode 14 to inject holes from the anode 12 to the luminous layer 13c and simultaneously inject electrons from the cathode 14 to the luminous layer 13c.

Then, the electrons and holes recombine to be in an excited state in the luminous layer 13c, and energy of the excited state is transformed to a light which is emitted from the luminous layer 13c.

A film formation equipment 15 for formation of the organic layer 13 of the organic EL element 10 will now be explained.

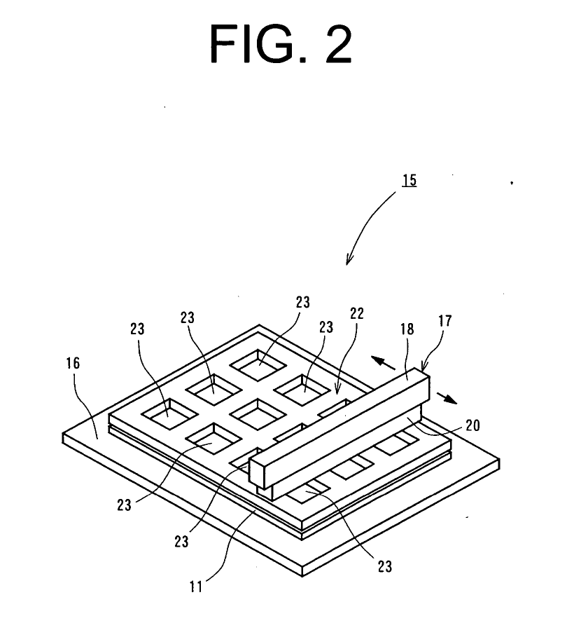

The film formation equipment 15 shown in FIG. 2 incorporates a chamber (not shown) capable of maintaining a prescribed vacuum level.

Provided in the chamber is a mounting table 16 on which a substrate is mounted.

Disposed above the mounting table 16 is a deposition source 17 capable of emitting an organic material in a direction toward the substrate and interposed between the deposition source 17 and the substrate is a mask 22.

Explanation of the deposition source 17 is given as follows. That is, the elongated deposition source housing 18 designed to have a width greater than that of the substrate is supported by a reciprocating means, not shown, which allows the deposition source housing 18 to reciprocate linearly in a direction orthogonal to the longitudinal direction of the housing 18, horizontally in a back and forth motion.

The deposition source housing 18 is capable of containing organic materials as a deposition material and in addition, has a plurality of outlets 19 which are provided in a line along the longitudinal direction of the deposition source housing 18 so as to face the substrate.

Further, the deposition source housing 18 is designed to be heated and heating the deposition source housing 18 vaporizes or sublimes an organic material, and the vaporized or sublimed organic material is emitted through the outlets 19.

Moreover, a frame-shaped shield 20 is attached to the deposition source housing 18 while extending downward so as to surround in a lateral direction a space below the deposition source housing 18 with the outlets 19. A length of the shield 20 is substantially the same length as a distance between the deposition source housing 18 and a heating member 22d of a mask 22, described below.

Thus constructed deposition source 17 is capable of reciprocating linearly with the help of the reciprocating means and further emitting a vaporized or sublimed organic material in the shape of a strip through the outlets 19 in a direction towards the glass substrate 11 as if a curtain flow of the organic material were emitted.

An explanation of the mask 22 will now be given.

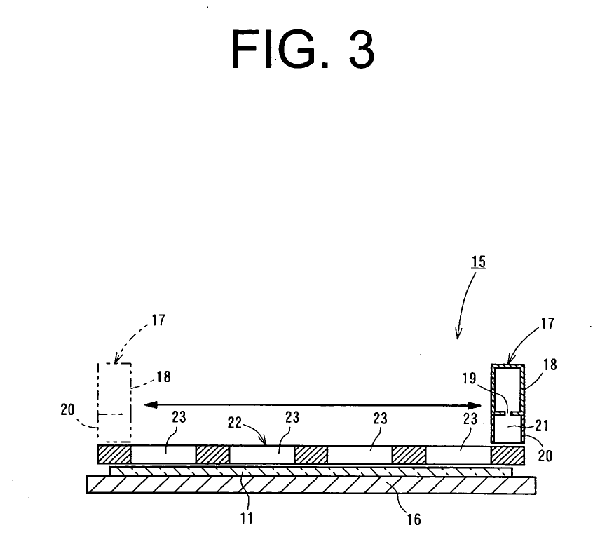

The mask 22 shown in FIG. 2 and FIG. 3 is designed to be substantially the same size as the glass substrate 11 and fixed to the substrate via a mask support means (not shown), so that its position relative to the substrate is not changed.

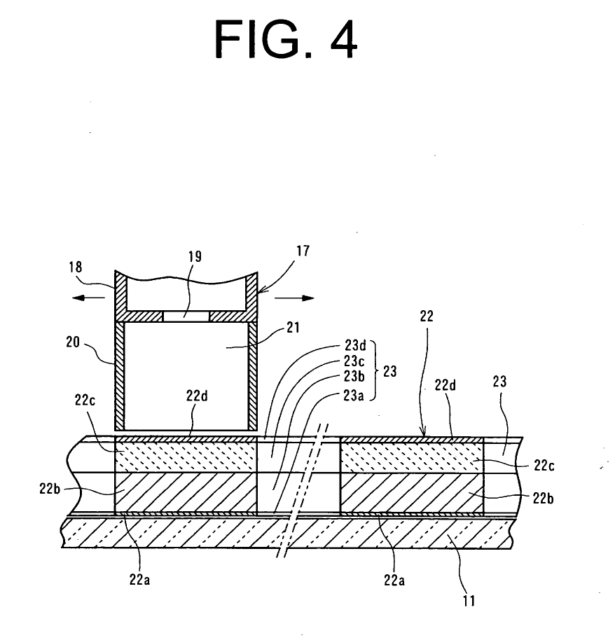

The mask 22 in this embodiment has a plurality of openings 23 provided to form deposition layers in a desired pattern and in addition, has a multi-layered structure consisting of layers laminated in upper/lower directions, as shown in FIG. 4.

The mask 22 includes: a mask body 22a closest to the glass substrate 11; a cooling member 22b provided on the mask body 22a; a heat insulation member 22c provided on the cooling member 22b; and the heating member 22d positioned closest to the deposition source 17 and provided on the heat insulation member 22c.

A lowest layer of the mask body 22a is typically a thin metal plate with a thickness of about 0.2 mm and has a plurality of openings 23a for forming an organic layer 13 into a desired pattern.

Further, a width of the opening 23a of the mask body 22 may be designed so that one side of the opening 23a equals 2 inches.

The cooling member 22b formed on the mask body 22a is provided to cool the mask body 22a and prevents the mask body 22a from being heated.

The cooling member 22b of the embodiment has a thickness of about 5 mm, and a pipe (not shown) with a small diameter is inserted in the cooling member 22b, a cooling medium receives heat while flowing through the pipe, and is later cooled in a radiator, not shown, provided outside the mask 22. After leaving the radiator, the cooled cooling medium returns to the cooling member 22b.

The heat insulation member 22c provided on the cooling member 22b serves to block heat from the below-described heating member 22d, so that the heat is not transferred to the mask body 22a, and is formed of glass fiber with a thickness of about 3 mm in this embodiment.

The heating member 22d formed on the heat insulation member 22c serves to prevent deposition of organic materials emitted from the deposition source 17 on the mask 22.

The heating member 22d of this embodiment is a thin metal plate with a thickness of about 0.5 mm and a high resistivity. A power supply device, not shown, is connected via interconnections, not shown, to the heating member so that current passes from a portion of the heating member to another portion thereof. Upon deposition, current is supplied from the power supply device via the interconnections so that the current passes through the heating member 22d, causing the heating member 22d to be heated to a temperature higher than a vaporization temperature or sublimation temperature of the organic material.

Therefore, when the heating member 22d is being heated, and even when the organic material emitted from the deposition source 17 is attached to the heating member 22d, the organic material is in no way deposited thereon, and is emitted from the heating member 22d as if the material were reflected therefrom.

It is noted that in this embodiment, the cooling member 22b, the heat insulation member 22c and the heating member 22d each have a plurality of openings 23b, 23c, 23d aligned with the plurality of openings 23a provided in the mask body 22a, and those openings 23a to 23d form the openings 23 of the mask 22.

Next, the manner in which organic materials are deposited on the substrate by the film formation equipment 15 will be explained.

An example in which the hole injection layer 13a, as a part of the organic layer 13 is formed on the glass substrate 11, having the anode 12 formed thereon, will be now explained.

First, the glass substrate 11, having the anode 12 formed thereon, and the mask 22 are fixed so that the mask body 22a faces the substrate. They are then loaded into a chamber where a prescribed vacuum level is maintained.

Then, the deposition source housing 18 of the deposition source 17 is heated, and the organic material for the hole injection layer 13a is emitted through the outlets 19 while the cooling medium passes through the small diameter pipe of the cooling member 22b of the mask 22, preventing overheating of the mask body 22a.

Thereafter, by activating the reciprocating means, the deposition source 17 moves linearly and horizontally along the upper surface of the mask 22. When the deposition source 17 passes above the openings 23 of the mask 22, the organic material from the deposition source 17 is guided through the outlets 19 and is emitted in the shape of a strip toward the glass substrate 11.

The emitted organic material passes through the openings 23 of the mask 22 and the organic material having passed therethrough is deposited on the glass substrate 11.

Since the deposition source 17 moves all over the upper surface of the mask 22, the deposition source 17 passes above all portions of the glass substrate 11 corresponding to the openings 23. This allows the organic material to be emitted from a direction substantially vertical to the glass substrate 11 to all portions of the glass substrate 11 corresponding to the openings 23.

At this point, although a part of the organic material emitted from the deposition source 17 is not deposited on the glass substrate 11, but is emitted onto the heating member 22d of the mask 22, heat contained in the emitted organic material and radiated heat from the deposition source housing 18 are applied to the heating member 22d so that the heating member 22d is heated to a temperature higher than the vaporization temperature or sublimation temperature of the organic material. Therefore, even when the organic material is attached to the heating member 22d, the organic material is never deposited thereon as it is and is immediately emitted from the heating member 22d.

It is noted that although the heating member 22d is positioned to receive heat, heat from the heating member 22d is blocked by the heat insulation member 22c and further is cooled by the cooling member 22b, thereby preventing the mask body 22a from being heated and thermally expanded.

When the deposition source 17 faces the heating member 22d, the deposition source housing 18, the shield 20 and the heating member 22d form a nearly completely enclosed space 21 as shown in FIG. 4, or depending on a position of the deposition source 17, those components in combination with the glass substrate 11 form a nearly completely enclosed space 21.

Since the heating member 22d is heated by heat contained in the emitted organic material and radiated heat from the deposition source 17, to a temperature higher than the vaporization heat or sublimation heat of the organic material, the organic material emitted from the deposition source 17 through the outlets 19 is immediately re-emitted to the space 21 even when it is attached to the heating member 22d.

Then, because the space 21 is nearly completely enclosed by the deposition source housing 18, the shield 20 and the heating member 22d, almost all of the organic material emitted to the space 21 remains in the space 21, and when the deposition source 17 moves to face a next opening 23, probability of deposition of the organic material on the glass substrate 11 becomes higher. As such, linearly reciprocating the deposition source 17 above the mask 22, while repeatedly depositing the organic material on the substrate, allows the hole injection layer 13a with a prescribed thickness to be formed in a desired pattern on the glass substrate 11.

It should be noted that since the organic layer 13 to be formed by deposition consists of a plurality of layers 13a to 13e of different materials and accordingly different organic materials will be sequentially deposited, typically, the substrate on which deposition has been performed by the film formation equipment 15 is in many cases transferred to another film formation equipment.

In this case, only the substrate on which deposition has been performed is usually transferred to a subsequent film formation equipment where a different organic material is deposited using a different mask, but in this embodiment the organic material is scarcely deposited on the mask 22 in this embodiment and therefore the mask 22, having been used for deposition in one film formation equipment 15, can be transferred together with the substrate to the subsequent film formation equipment.

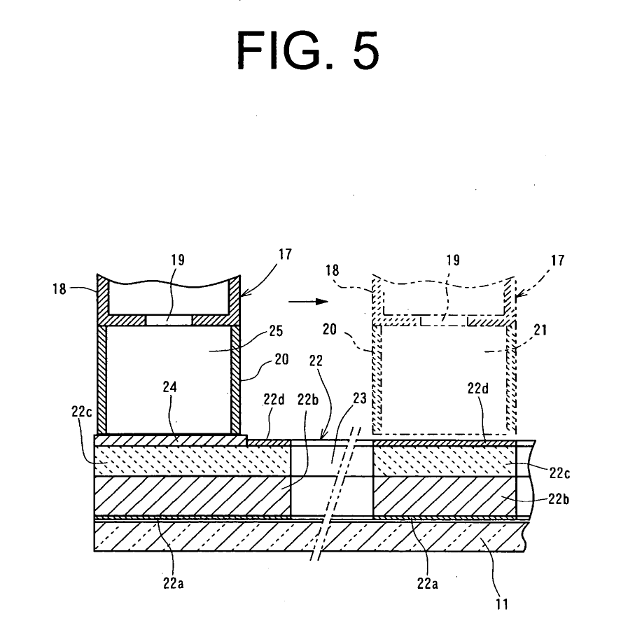

In a case where only the glass substrate 11 on which deposition has been performed is transferred to the subsequent film formation equipment and the different organic material is deposited using a different mask in the subsequent film formation equipment, as shown in FIG. 5, a contacting member 24 may be provided in contact with or in nearly contact with the shield 20 around the periphery of the mask 22, so that the deposition source 17 of the film formation equipment 15 can wait ready while facing the mask 22.

Preferably, the contacting member 24 has a height such that the contacting member 24 contacts the shield 20 or the shield 20 can approach the contacting member 24 more closely than it can approach the heating member 22d. Additionally, the contacting member 24 is preferably heated as the heating member 22d is heated.

Thus, a space 25 is enclosed by the deposition source housing 18, the shield 20 and the contacting member 24 to a greater extent than the space 21 is enclosed by the deposition source housing 18, the shield 20 and the heating member 22, i.e., the space 25 is substantially completely enclosed.

Providing the contacting member 24 in a specific position around the periphery of the mask 22, the position at which the deposition source 17 is able to wait ready, allows the organic material emitted from the deposition source 17 to be substantially confined in the space 25 while dispersion of the organic material in all directions is prevented when the glass substrate 11 is waiting for receiving deposition.

The mask 22, a film formation method using the mask 22 and the film formation equipment 15 according to this embodiment produce the following beneficial effects.

(1) Since the heating member 22d is provided above the mask body 22a of the mask 22 and the organic material is re-vaporized or re-sublimed by the heating member 22d, deposition of the organic material on the mask 22 can be prevented. Further, because current passing through the heating member 22d causes the self-heating of the heating member 22d, a temperature of the heating member 22d can be relatively easily controlled and further stabilized by controlling the amount of current passing therethrough.

(2) The mask 22 has a multi-layered structure and when the thickness of the structure is increased, the strength of the mask 22 is enhanced. For this reason, a decrease in dimensional accuracy of the organic layer 13 due to bending of the mask 22 can be prevented and further durability of the mask 22 is improved while handling of the mask 22 is facilitated.

(3) Providing the heat insulation member 22c and the cooling member 22b in the mask 22 prevents thermal expansion of the mask body 22a and the glass substrate 11, and thereby prevents a decrease in the dimensional accuracy of the organic layer 13 due to thermal expansion.

(4) Since the glass substrate 11 is mounted on the mounting table 16 and then the organic material is deposited from above the glass substrate 11, bending of the glass substrate 11 due to its weight never occurs, which prevents a decrease in the dimensional accuracy of the organic layer 13 due to the bending of the glass substrate 11.

(5) Since the deposition source 17 moves linearly, the organic material is emitted in the shape of a strip from the deposition source 17 like a curtain flow of the organic material, and the organic material is emitted from a direction substantially vertical to the substrate, the organic material is scarcely susceptible to influence of a shadow due to the thickness portion of the mask 22. This allows uniform formation of the organic layer 13 on the glass substrate 11 and further prevents a decrease in the dimensional accuracy of the organic layer 13.

(6) Providing the contacting member 24 in the specific position of the mask 22, the position at which the deposition source 17 is able to wait ready, allows formation of the space 25 enclosed by the deposition source housing 18, the shield 20 and the contacting member 24 and further allows the organic material emitted from the deposition source 17 to be substantially confined in the space 25, and therefore, when the glass substrate 11 is waiting for receiving deposition, the organic material emitted from the deposition source 17 is never wasted. Further, when deposition is initiated, the organic material confined in the space 25 can be immediately used for deposition on the glass substrate 11.

(7) Because the shield 20 is mounted to the deposition source housing 18, the organic material emitted from the outlets 19 can be guided along the shield 20 and the organic material can be emitted in the shape of a strip from the deposition source 17. This allows a deposition layer formed by deposition of an organic material to be more uniform over the glass substrate.

(8) When the deposition source 17 faces the heating member 22d, the deposition source housing 18, the shield 20 and the heating member 22d form a nearly completely enclosed space 21 as shown in FIG. 4, or depending on a position of the deposition source 17, those components in combination with the glass substrate 11 form a nearly completely enclosed space 21. The heating member 22d is heated by heat of the emitted organic material and radiated heat from the deposition source 17 to a temperature higher than the vaporization temperature or sublimation temperature of the organic material and therefore, even when the organic material is attached to the heating member 22d, the organic material emitted from the deposition source 17 through the outlets 19 is immediately re-emitted to the space 21. For this reason, the organic material is never deposited on a portion of the substrate other than a portion corresponding to the openings 23 and therefore the utilization efficiency of the organic material can be improved.

(9) The organic material is scarcely deposited on the mask 22. For this reason, even when deposition operation is repeated, the thickness of the mask 22 appears to be little changed, thereby allowing deposition to be always performed under constant conditions. Further, since the probability of the mask being contaminated by the organic material is extremely low, it also becomes possible for different organic materials to be deposited using the same mask in different chambers.

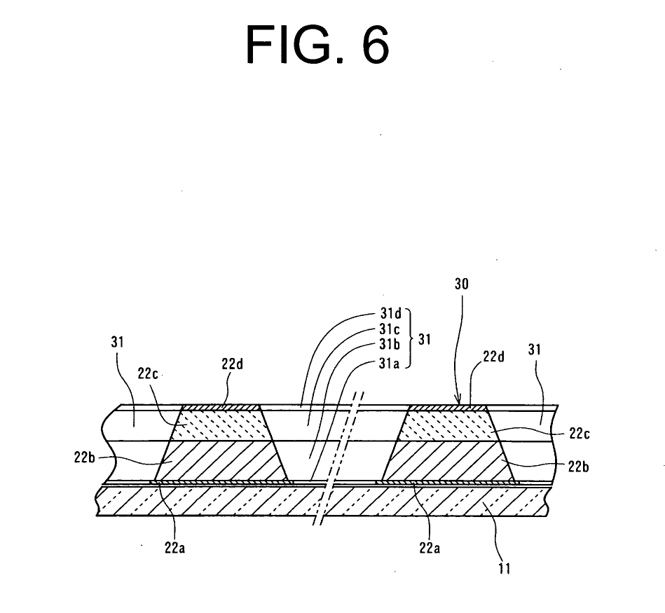

Now, a mask 30, according to a second embodiment, will be explained with reference to FIG. 6.

In this embodiment, openings 31 of the mask 30 are different from those in the first embodiment.

In this embodiment, for explanatory convenience, some of the numerals used in the first embodiment are commonly used, and explanation of the configuration common or analogous to the first embodiment is omitted.

As shown in FIG. 6, the mask 30 includes, from the bottom up, a mask body 22a, the cooling member 22b, the heat insulation member 22c and the heating member 22d, and openings 31b, 31c, 31d of the cooling member 22b, the heat insulation member 22c and the heating member 22d all correspond substantially to an openings 31a of the mask body 22a.

The expression that the openings 31b to 31d correspond substantially to the opening 31a in the embodiment means that the opening 31a and the openings 31b to 31d are similar to or substantially similar to each other and further dimensions of the openings 31a to 31d are close to one another.

The explanation of those openings 31a to 31d will now be given in detail. The openings 31b to 31d of the cooling member 22b, the heat insulation member 22c and the heating member 22d are designed to be larger than the opening 31a of the mask body 22a, and the opening 31c of the heat insulation member 22c is designed to be larger than the opening 31b of the cooling member 22b, and further, the opening 31d of the heating member 22d is designed to be larger than the opening 31c of the heat insulation member 22c.

The reason for this is that influence of a shadow due to the thickness portion of the mask 30 needs to be more securely removed and a decrease in the dimensional accuracy of the organic layer 13 to be deposited on a substrate needs to be avoided.

In this embodiment, the opening 31 of the mask 30 is formed by inclined surfaces sequentially formed in a direction from the heating member 22d toward the mask body 22a.

Then, using the mask 30 of this embodiment, an organic material is deposited on the substrate in a manner similar to the first embodiment and in this case, the organic material is less susceptible to influence of the thickness of the mask 30 than to influence of the thickness of the mask 22 of the first embodiment.

The mask 30, a film formation method using the mask 30 and a film formation equipment 15 according to this embodiment produce the following beneficial effects in addition to the effects (1) to (9) produced by the first embodiment.

(10) Since the opening 31 is formed in the mask 30 by the inclined surfaces sequentially formed in a direction from the heating member 22d toward the mask body 22a, the organic material emitted from the deposition source 17 is scarcely susceptible to influence of the thickness of the mask 30. Accordingly, the dimensional accuracy of the organic layer 13 formed by depositing the organic material on the glass substrate 11 is increased.

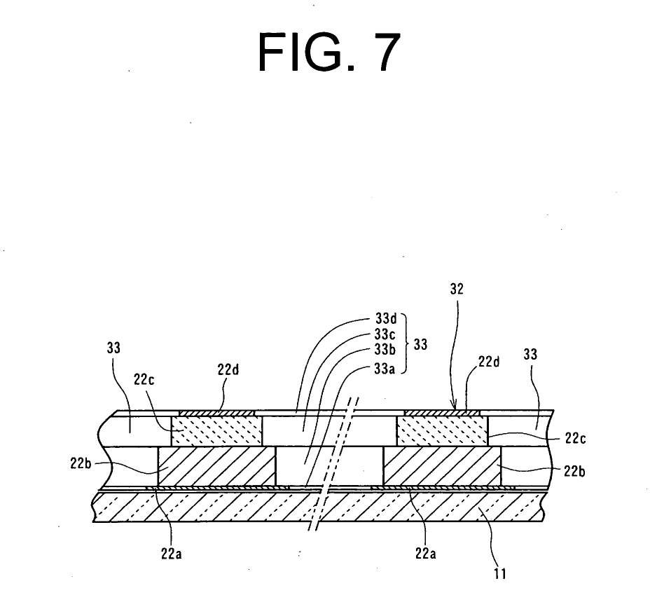

A first modification example of the mask 30 according to the second embodiment will now be explained with reference to FIG. 7.

Similarly to the mask 30 previously explained, a mask 32 according to the first modification example includes the mask body 22a, the cooling member 22b, the heat insulation member 22c, the heating member 22d.

Further, although in the mask 32, openings 33b, 33c, 33d of the cooling member 22b, the heat insulation member 22c and the heating member 22d are designed to be larger than an opening 33a of the mask body 22a, the individual openings 33a to 33d of the mask body 22a, the cooling member 22b, the heat insulation member 22c and the heating member 22d are formed orthogonally to the planes of the individual components 22a to 22d.

Further, the openings 33b to 33d of an opening 33 other than the opening 33a of the mask body 22a are designed to be larger in the order of the opening 33b, the opening 33c and the opening 33d.

Thus, the opening 33 of the mask 32 consists of the openings 33a to 33d of the individual components 22a to 22d in which the openings 33a to 33d together form a stepped opening.

When using the mask 32, deposition is not affected by the thickness of the mask 32 and a decrease in the dimensional accuracy of the organic layer 13 on the glass substrate 11 can be prevented.

Further, because the individual openings 33a to 33d of the mask body 22a, the cooling member 22b, the heat insulation member 22c and the heating member 22d are formed orthogonally to the planes of the individual components 22a to 22d, processing such as formation of the openings 33a to 33d in the individual components 22a to 22d is relatively simplified and further, fabrication of the mask 32 becomes facilitated because, for example, the openings 33a to 33d are independently formed in the individual components 22a to 22d.

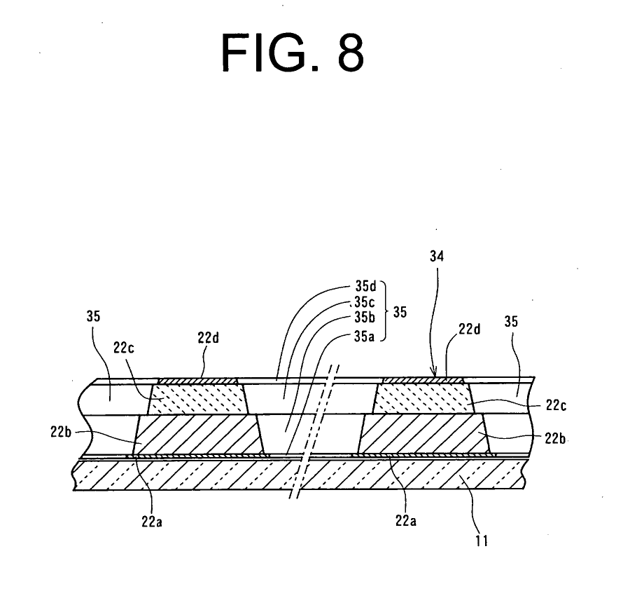

A mask 34 according to a second modification example will now be explained with reference to FIG. 8.

Similarly to the mask 30, in the mask 34 according to the second modification example, openings 35b to 35d of the cooling member 22b, the heat insulation member 22c and the heating member 22d are designed to be larger than an opening 35a of the mask body 22a.

In the mask 34, the cooling member 22b, the heat insulation member 22c and the heating member 22d are configured so that the individual openings 35b to 35d are formed by inclined surfaces that the individual components 22b to 22d have, and the inclined surfaces of the individual components 22b to 22d are designed so as not to be coplanar.

Consequently, although the individual components 22b to 22d have the inclined surfaces forming the openings 35b to 35d, when viewing those openings in cross-section, the opening 35 appears to have a multi-step configuration.

The mask 34 according to the second modification example produces beneficial effects that are similar to those of the embodiments using the masks 30, 32 in that variations in quality of the organic layer 13 on the glass substrate 11 can be prevented.

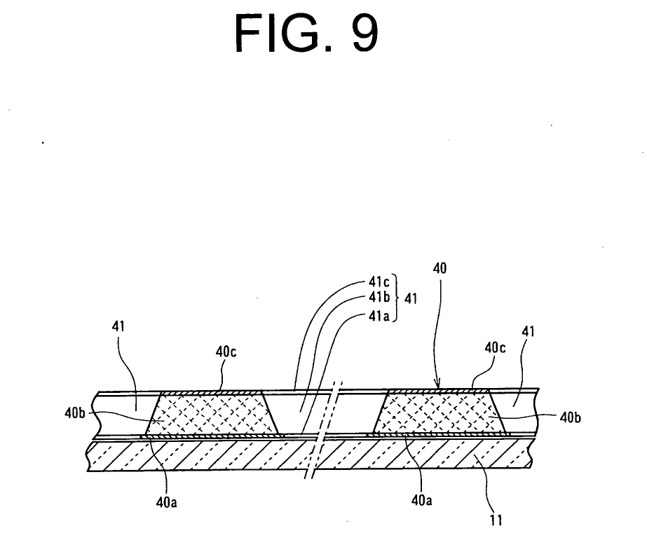

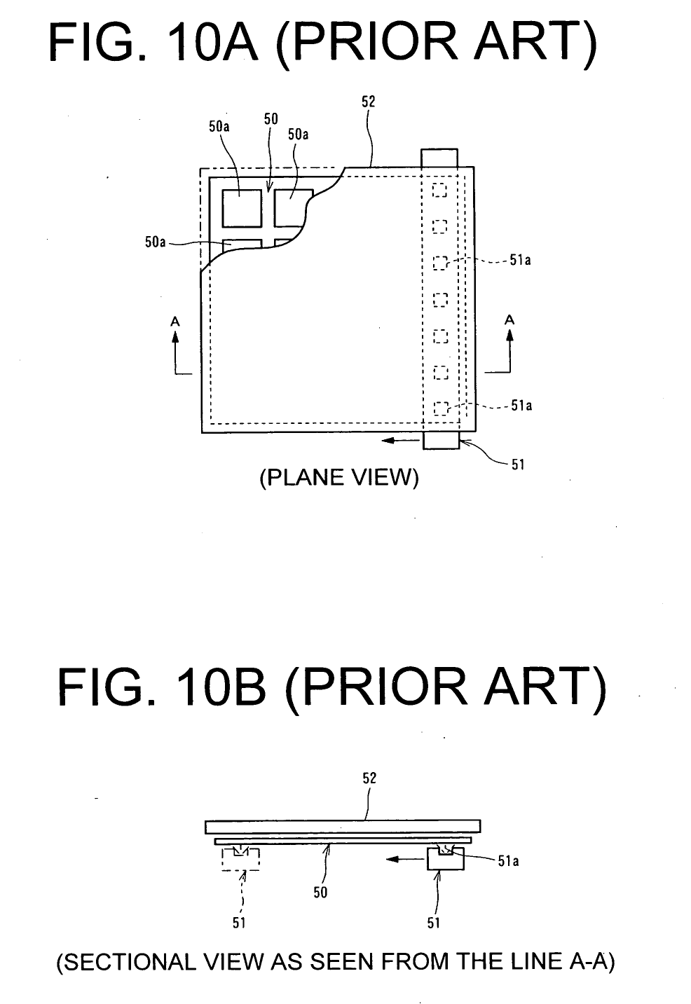

A mask 40 according to a third embodiment will now be explained with reference to FIG. 9.

The mask 40 according to the embodiment includes a mask body 40a, a cooling member 40b provided on the mask body 40a, and a heating member 40c provided on the cooling member 40b.

Similarly to the aforementioned embodiment, in this embodiment, openings 41b, 41c corresponding substantially to an opening 41a of the mask body 40a, are provided respectively in the heating member 40c and the cooling member 40b, and further, also prevent influence of a shadow due to the thickness portion of the mask 40. The openings 41b, 41c, in combination with each other, form a common inclined surface and form an opening 41 of the mask 40.

In the mask 40 according to this embodiment, the cooling member 40b is configured to include a thermoelectric element having cooling function upon passage of current.

In more detail, this embodiment employs a Peltier element constituted of a P type thermoelectric semiconductor and N type semiconductor containing bismuth/antimony/tellurium (Bi/Sb/Te) as a raw material, in which heat retrieved from the cooling member 40b is transferred to the heating member 40c to cool the mask body 40a.

Accordingly, even when the heating member 40c of the mask 40 is being heated upon deposition, passage of current through the Peltier element of the cooling member 40b allows the mask body 40a to be cooled while heat from the heating member 40c is blocked by the cooling member 40b, thereby preventing occurrence of thermal expansion of the mask body 40a.

Further, since heat received by the cooling member 40b is transferred to the heating member 40c, the heating member 40a can be effectively heated.

According to this embodiment, the following additional beneficial effects can be produced.

(11) Because heat received by the cooling member 40b can be transferred to the heating member 40c, cooling of the substrate and heating of the heating member 40c can be effectively performed.

(12) Since formation of a heat insulation layer in the mask 40 can be omitted, the thickness of the mask 40 can be prevented from being extremely large, thereby allowing influence of the thickness of the mask 40 to be further reduced.

(13) Control of current passing through the thermoelectric element of the cooling member 40b allows cooling of the mask body 40a to be performed stably, depending on circumstances.

It should be appreciated that the invention is not limited to the above embodiments but may be changed in various ways without departing from the principle of the invention. For instance, the following changes may be made.

In the first to third embodiments, although the mask is disposed on the substrate and further the organic material emitted from the deposition source above the mask is deposited on the upper surface of the substrate, it may, for example, be disposed below the substrate and the deposition source may be positioned below the mask in order to deposit the organic material emitted from the deposition source on a lower surface of the substrate.

As mentioned above, when the mask is disposed above the deposition source, the mask bends due to its weight and as a result, there was a problem of decreasing the dimensional accuracy of a deposition material to be deposited. However, since the mask according to the invention has a greater rigidity than the conventional mask, the extent to which the mask bends due to its weight becomes smaller and the dimensional accuracy of the deposition material to be deposited is also improved.

Further, more generally, as long as the mask is interposed between the substrate and the deposition source and the heating member of the mask is positioned so as to face the deposition source, the substrate, the mask and the deposition source may be arranged in any direction such as a vertical direction or a sideways direction.

Although in the first to third embodiments, the deposition source is configured to move relatively to the substrate incorporating the mask thereon and placed on the mounting table, the mask and substrate may be configured to move together while the deposition source is fixed. Or the substrate incorporating the mask thereon and the deposition source may be configured to move in directions opposite to each other.

Although in the first to third embodiments, the deposition material emitted from the deposition source is the organic material for the organic EL element, it is not limited to the organic material for the organic EL element, but would, for example, be a metallic material or an inorganic material other than the metallic material.

Although in the first and second embodiments, the material of the heat insulation member of the mask is the glass fiber, it may instead be, for example, a resin, a ceramic material, etc. and would be any material having an ability to prevent heat transfer to the mask body.

Although in the first and second embodiments, the heating member of the mask is configured to self-heat by current passing through the heating member, it may, for example, be configured to additionally include a heating means such as a nichrome wire provided on or inside the heating member.

Further, the heating member may be configured to be heated by heat of the deposition material emitted from the deposition source and radiated heat from the deposition source. In this case, a need to additionally provide the heating means is eliminated.

Although in the first and second embodiments, the mask includes the heat insulation member and the cooling member, it may, for example, be configured to include a heating member, a heat insulation member and a mask body. In this case, to prevent heat from the heating member from being transferred to the mask body, a material having an extremely effective heat-blocking ability is preferably employed. This prevents thermal expansion of the mask body and further prevents the thickness of the mask from being extremely large.

Therefore, the present examples and embodiments are to be considered as illustrative and not restrictive and the invention is not to be limited to the details given herein but may be modified.

1. A mask interposed between a deposition source and a substrate for deposition, the mask having an opening for permitting a deposition material emitted from the deposition source to pass therethrough and forming a deposition layer of a desired pattern on the substrate, the mask comprising:
a mask body having the opening; and
a heating member which is heated during deposition and is arranged on a side of the mask body that faces the deposition source, the heating member having an opening which corresponds substantially to the opening of the mask body.

2. The mask according to claim 1, wherein the heating member is heated by heat from the deposition source and from the deposition material.

3. The mask according to claim 1, wherein the heating member has a means for self-heating.

4. The mask according to claim 1, wherein the opening of the heating member is designed so as to be larger than the opening of the mask body.

5. The mask according to claim 1, wherein the deposition layer is an organic layer for an organic electroluminescent element.

6. The mask according to claim 1 further comprising a heat insulation member interposed between the heating member and the mask body, the heat insulation member having an opening which corresponds substantially to the opening of the mask body and the opening of the heating member.

7. The mask according to claim 6, wherein the opening of the heat insulation member is designed so as to be larger than the opening of the mask body.

8. The mask according to claim 1, further comprising a cooling member contacting the mask body for cooling the mask body, the cooling member being arranged on a side of the mask body facing the deposition source, the cooling member having an opening which corresponds substantially to the opening of the mask body.

9. The mask according to claim 8, wherein the opening of the cooling member is designed so as to be larger than the opening of the mask body.

10. A film formation method using a mask for forming a deposition layer of a desired pattern on a substrate, the mask including a mask body and a heating member, the method comprising the steps of:
fixing the substrate and the mask so that the mask body faces the substrate;
providing a deposition source that emits a deposition material so as to face a side of the mask corresponding to the heating member; and
heating the heating member of the mask while depositing the deposition material on the substrate.

11. The method according to claim 10, wherein the mask further comprises a cooling member, the method comprising the additional step of:
cooling the mask body using the cooling member while depositing the deposition material on the substrate.

12. The method according to claim 10, wherein the method comprises the additional step of:
moving the substrate and the deposition source relatively while depositing the deposition material on the substrate.

13. A film formation equipment for forming a deposition layer on a substrate comprising:
a deposition source that emits a deposition material toward the substrate;
a mask interposed between the substrate and the deposition source for forming a deposition layer of a desired pattern on the substrate, the mask comprising:
a mask body; and
a heating member arranged on a side of the mask body that faces the deposition source.

14. The film formation equipment according to claim 13, further comprising a shield that extends from the deposition source toward the mask, the length of the shield being substantially equal to a distance between the deposition source and the heating member.

15. The film formation equipment according to claim 13, further comprising a means for moving the substrate and the deposition source relatively.
